(19) United States
(12) Patent Application Publication
(10) Pub. No.: US 2014/0045341 A1
(43) Pub. Date: Feb. 13, 2014

(54) PATTERN FORMING METHOD

(71) Applicant: KABUSHIKI KAISHA TOSHIBA, Tokyo (JP)

(72) Inventor: Hiroki YONEMITSU, Yokohama-Shi (JP)

(73) Assignee: KABUSHIKI KAISHA TOSHIBA, Tokyo (JP)

(21) Appl. No.: 13/762,892

(22) Filed: Feb. 8, 2013

(30) Foreign Application Priority Data
Aug. 9, 2012 (JP) 2012-176841

(51) Int. Cl. H01L 21/308

(52) U.S. Cl. CPC H01L 21/3088
USPC 438/763

(57) ABSTRACT

According to one embodiment, a pattern forming method includes forming a physical guide, in which at least an upper part of a side wall surface of a concave section is an inclined surface, on a film to be processed, forming a polymer layer containing at least two kinds of segments inside the concave section of the physical guide, microphase-separating the polymer layer, to form self-assembled polymer domains including a first polymer section and a second polymer section, and processing the film to be processed by use of the self-assembled polymer domains.

### CROSS REFERENCE TO RELATED APPLICATION

This application is based upon and claims benefit of priority from the Japanese Patent Application No. 2012-176841, filed on Aug. 9, 2012, the entire contents of which are incorporated herein by reference.

### FIELD

Embodiments described herein relate generally to a pattern forming method.

### BACKGROUND

As a lithography technique in a semiconductor element manufacturing process, a double patterning technique by ArF-immersion exposure, EUV lithography, nanoimprinting and the like are known. A conventional lithography technique has held a variety of problems such as a cost increase and through-put deterioration, which have occurred with finer processing of a pattern.

Under such circumstances, application of directed self-assembly (DSA) to the lithography technique has been expected. Since DSA is generated by a voluntary behavior such as energy stabilization, a pattern with high dimensional accuracy can be formed. Especially, a technique of using microphase separation of a high-polymer block copolymer enables formation of periodic structures in a variety of shapes of several nm to several hundred nm by means of simple coating and an anneal process. The high-polymer block copolymer can be changed in shape to a spherical shape, a cylindrical shape, a lamella shape or the like in accordance with a composition ratio of blocks, and can be changed in size in accordance with a molecular weight, thereby to form a dot pattern, a hole or pillar pattern, line patterns or the like with a variety of dimensions.

Formation of a desired pattern in a broad range by use of DSA requires provision of a guide for controlling a generating location of a polymer phase formed by DSA. There are known as the guide a physical guide (graphoepitaxy) that has a concavo-convex structure and forms a microphase separation pattern in its concave section, and a chemical guide (chemical epitaxy) that is formed in a lower layer of the DSA material and controls based on a difference in its surface energy a forming location of the microphase separation pattern.

In the case of using the physical guide, it has been required to improve embedment properties of the DSA material into the concave section of the physical guide.

### BRIEF DESCRIPTION OF THE DRAWINGS

FIG. 1 is a process sectional view for explaining a pattern forming method according to a first embodiment of the present invention;

FIG. 2 is a process sectional view subsequent to FIG. 1;

FIG. 3 is a process sectional view subsequent to FIG. 2;

FIG. 4 is a process sectional view subsequent to FIG. 3;

FIG. 5 is a process sectional view subsequent to FIG. 4;

FIG. 6 is a process sectional view subsequent to FIG. 5;

FIG. 7 is a process sectional view subsequent to FIG. 6;

FIG. 8 is a process sectional view for explaining a pattern forming method according to a second embodiment of the present invention;

FIG. 9 is a process sectional view subsequent to FIG. 8;

FIG. 10 is a process sectional view subsequent to FIG. 9;

FIG. 11 is a process sectional view subsequent to FIG. 10;

FIG. 12 is a process sectional view subsequent to FIG. 11;

FIG. 13 is a process sectional view subsequent to FIG. 12;

FIG. 14 is a process sectional view subsequent to FIG. 13;

FIG. 15 is a sectional view of a physical guide according to a modified example;

FIGS. 16A and 16B are sectional views of a physical guide according to a modified example; and

FIG. 17 is a sectional view of a physical guide according to a modified example.

### DETAILED DESCRIPTION

According to one embodiment, a pattern forming method includes forming a physical guide, in which at least an upper part of a side wall surface of a concave section is an inclined surface, on a film to be processed, forming a polymer layer containing at least two kinds of segments inside the concave section of the physical guide, microphase-separating the polymer layer, to form self-assembled polymer domains including a first polymer section and a second polymer section, and processing the film to be processed by use of the self-assembled polymer domains.

Embodiments will now be explained with reference to the accompanying drawings.

### First Embodiment

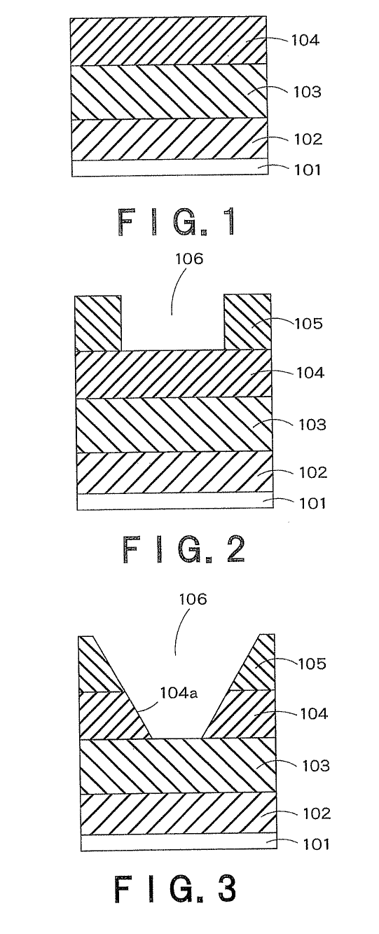

A pattern forming method according to a first embodiment will be described using FIGS. 1 to 7.

First, as shown in FIG. 1, a film 102 to be processed which is made up of an amorphous silicon film with a film thickness of 50 nm, for example, is formed on a substrate 101. Then, coating of SOC (Spin-On Carbon) is applied onto the film 102 to be processed and subjected to a baking treatment, to form an SOC film 103 with a film thickness of 100 nm. Further, coating of SOG (Spin-On Glass) is applied onto the SOC film 103 and subjected to the baking treatment, to form an SOG film 104 with a film thickness of 45 nm.

Next, as shown in FIG. 2, coating of a resist 105 is applied onto the SOG film 104 and subjected to exposure to light and development by ArF excimer laser, to form a desired hole pattern 106. A planar shape of the hole pattern 106 corresponds to microphase separation of a block copolymer which will be formed in a later process, and is a rectangular shape, a circular shape or the like.

Next, as shown in FIG. 3, the SOG film 104 is etched using the resist 105 as a mask. Herein, anisotropic etching is performed with a type of gas and pressure adjusted such that a side wall section of the hole pattern 106 in the resist 105 is sharpened so as to be tapered. Thereby, a hole side wall section of the etched SOG film 104 becomes an inclined surface 104a turning upward. After etching of the SOG film 104, the resist 105 is removed.

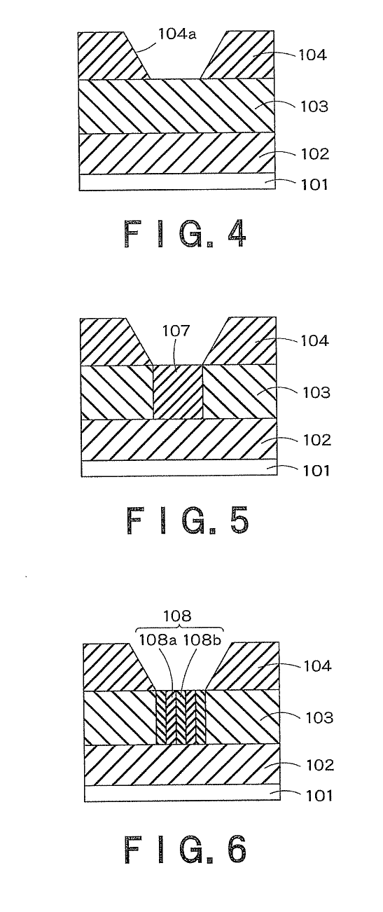

Next, as shown in FIG. 4, the SOC film 103 is etched using the SOG film 104 as a mask. Herein, anisotropic etching is performed with a type of gas and pressure adjusted such that a hole side wall section of the SOC film 103 becomes an almost vertical surface.

This leads to formation of a physical guide which has the laminated SOC film 103 and SOG film 104, and in which an upper part (portion of the SOG film 104) of the side wall surface of the concave section is an inclined surface. At this time, angles formed between the hole side wall surfaces of the SOC film 103 and the SOG film 104 and a flat surface of the substrate 101 are respectively about 90° and about 70°.

Next, as shown in FIG. 5, coating of the block copolymer (DSA material) is applied. For example, a solution of polyethylene glycol monomethyl ether acetate (PGMEA), which contains a block copolymer (PS-b-PMMA) of polystyrene (PS) and polymethyl methacrylate (PMMA) with a concentration of 2.0 wt %, is spin-coated at a revolution speed of 1500 rpm.

The coated block copolymer flows into the hole section of the SOC film 103 along the inclined surface 104a of the SOG film 104, to form a block copolymer layer 107.

Next, as shown in FIG. 6, the substrate 101 is placed on a hot plate (not shown), to be heated at 110° C. for 90 seconds, and further heated in a nitrogen atmosphere at 220° C. for 3 minutes. Thereby, the block copolymer layer 107 forms a lamellar-shaped DSA phase (microphase separation pattern or self-assembled polymer domains) 108 which is alternatively arranged with a laminar first polymer section 108a containing a first polymer block chain and a laminar second polymer section 108b containing a second polymer block chain.

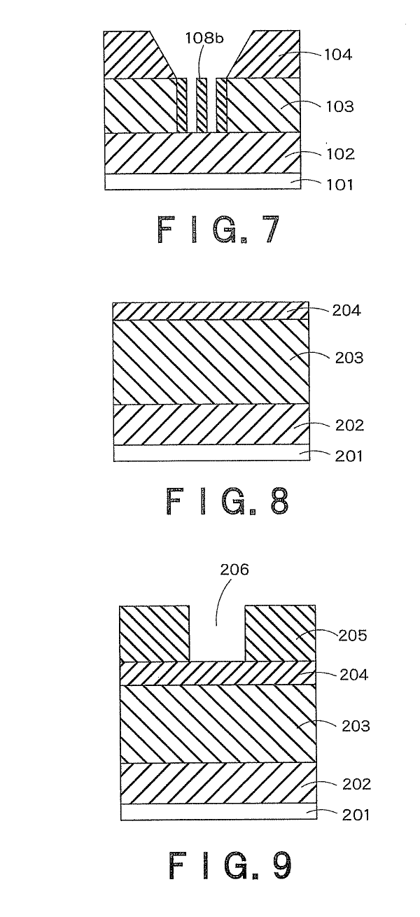

Next, as shown in FIG. 7, the first polymer section 108a (e.g. first polymer section 108a made up of PMMA) in the DSA phase 108 is selectively removed by a wet development treatment, thereby to give a line-and-space pattern with a high aspect ratio.

Subsequently, the film 102 to be processed is processed using the physical guide and the second polymer section 108b as a mask. This can lead to formation of the line-and-space pattern with a high aspect ratio in the film 102 to be processed.

As thus described, in the present embodiment, the physical guide made up of the laminated SOC film 103 and SOG film 104 is formed, and inclination is provided in the upper layer portion (SOG film 104), thereby allowing improvement in embedment properties of the DSA material into the concave section of the physical guide. It is possible to uniformly embed the DSA material throughout the substrate, so as to accurately form the DSA phase (microphase separation pattern).

Although the angles formed between the inclined surface 104a of the SOG film 104 and the flat surface of the substrate 101 has been made about 70° in the first embodiment, the angle is not restricted to this, and may be any angle so long as facilitating the block copolymer to flow into the inside of the hole section of the SOC film 103.

### Second Embodiment

A pattern forming method according to a second embodiment will be described using FIGS. 8 to 14.

First, as shown in FIG. 8, a film 202 to be processed which is made up of a silicon dioxide film with a film thickness of 100 nm, for example, is formed on a substrate 201. Then, an amorphous carbon film 203 with a film thickness of 200 nm is formed on the film 202 to be processed. Further, coating of SOG (Spin-On-Glass) is applied onto the amorphous carbon film 203 and subjected to the baking treatment, to form an SOG film 204 with a film thickness of 45 nm.

Next, as shown in FIG. 9, coating of a resist 205 is applied onto the SOG film 204 and subjected to exposure to light and development by ArF excimer laser to, to form a desired hole pattern 206. A planar shape of the hole pattern 206 corresponds to microphase separation of a block copolymer which will be formed in a later process, and is a rectangular shape, a circular shape or the like.

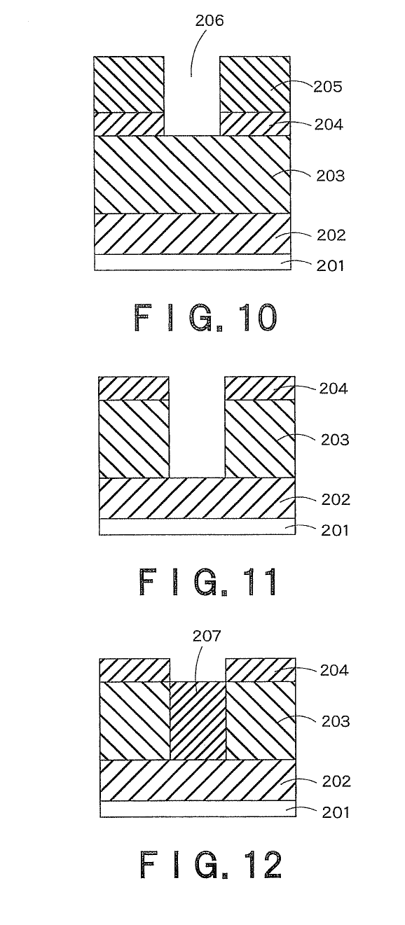

Next, as shown in FIG. 10, the SOG film 204 is etched using the resist 205 as a mask. After etching of the SOG film 204, the resist 205 is removed. A hole side wall section of the etched SOG film 204 becomes an almost vertical surface. Then the resist 205 is removed.

Next, as shown in FIG. 11, the amorphous carbon film 203 is etched using the SOG film 204 as a mask. A hole side wall section of the etched amorphous carbon film 203 becomes an almost vertical surface.

This leads to formation of a physical guide made up of the laminated amorphous carbon film 203 and SOG film 204. A contact angle of SOG to water is larger than that of amorphous carbon. The contact angle of SOG to water is about 80°, and the contact angle of amorphous carbon to water is about 40°. That is, an upper layer portion (SOG film 204) of the physical guide has higher water repellency than a lower layer portion (amorphous carbon film 203) thereof.

Next, as shown in FIG. 12, coating of a block copolymer (DSA material) is applied. For example, a solution of polyethylene glycol monomethyl ether acetate (PGMEA), which contains a block copolymer (PS-b-PMMA) of polystyrene (PS) and polymethyl methacrylate (PMMA) with a concentration of 2.0 wt %, is spin-coated at a revolution speed of 1500 rpm.

Under the influence of the SOG film 204 with high water repellency, the coated block copolymer has been facilitated to flow into the hole section of the amorphous carbon film 203, to form a block copolymer layer 207.

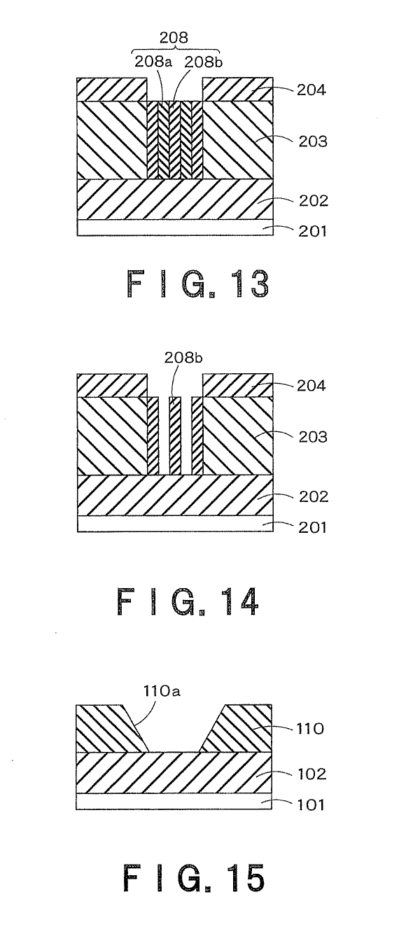

Next, as shown in FIG. 13, the substrate 201 is placed on a hot plate (not shown), to be heated at 110° C. for 90 seconds, and further heated in a nitrogen atmosphere at 220° C. for 3 minutes. Thereby, the block copolymer layer 207 forms a lamellar-shaped DSA phase (microphase separation pattern) 208 which is alternatively arranged with a laminar first polymer section 208a containing a first polymer block chain and a laminar second polymer section 208b containing a second polymer block chain.

Next, as shown in FIG. 14, the first polymer section 208a (e.g. first polymer section 208a made up of PMMA) in the DSA phase 208 is selectively removed by a wet development treatment, thereby to give a line-and-space pattern with a high aspect ratio.

Subsequently, the film 202 to be processed is processed using the physical guide and the second polymer section 208b as a mask. This can lead to formation of the line-and-space pattern with a high aspect ratio in the film 202 to be processed.

Accordingly, in the present embodiment, the physical guide with a laminated structure where the upper layer has higher water repellency than the lower layer is formed, to allow improvement in embedment properties of the DSA material into the concave section of the physical guide. It is possible to uniformly embed the DSA material throughout the substrate, so as to accurately form the DSA phase (microphase separation pattern).

Although the physical guide made up of the laminated SOC film 103 and SOG film 104 has been formed in the first embodiment, the materials constituting the physical guide are not restricted to these. The laminated structure of the SOC film 103 and the SOG film 104 is preferred in terms of reflection accuracy in lithography processing at the time of patterning the resist 105.

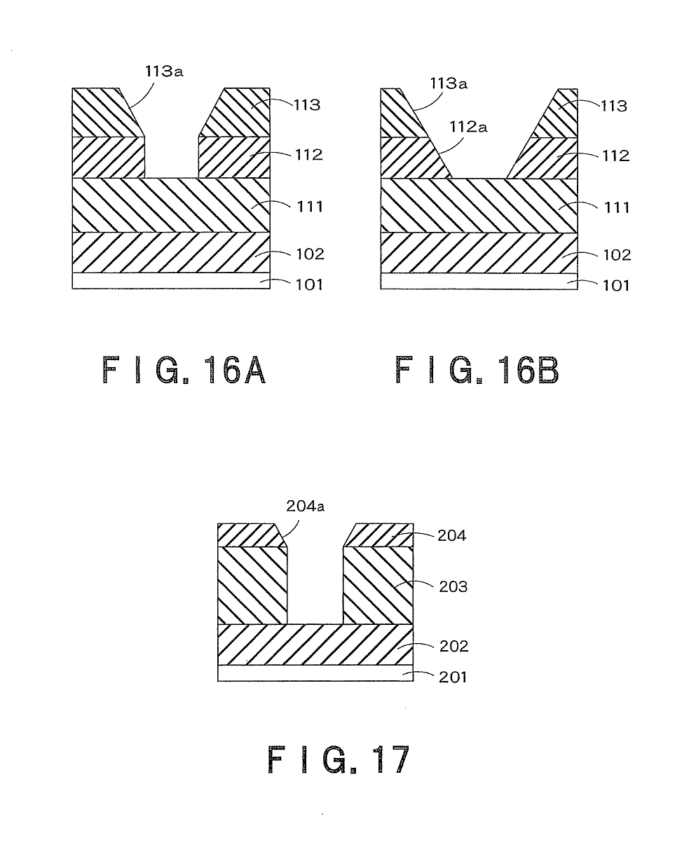

Although the physical guide with the laminated structure has been formed in the first embodiment, it may be a physical guide with a single layer 110 where the inclined surface 110a is provided on a hole side wall section as shown in FIG. 15. Further, the physical guide may have a structure of three or more layers. In the case of the three-layer structure, as shown in FIG. 16A, an inclined surface 113a may be provided only in a top layer 113, or inclined surfaces 113a and 112a may be provided on the top layer 113 and an intermediate layer 112. An angle formed between the inclined surface 113a and the flat surface of the substrate 101 is not larger than an angle formed between the inclined surface 112a and the flat surface of the substrate 101. Further, an inclined surface may be provided on at least part of a hole side wall section of a bottom layer 111.

Although the physical guide made up of the laminated amorphous carbon film 203 and SOG film 204 has been formed in the second embodiment, the materials constituting the physical guide are not restricted to these so long as the upper layer section has higher water repellency than the lower layer section. Further, in the above second embodiment, the physical guide may have a structure of three or more layers, and the top layer preferably has the highest water repellency.

Moreover, in the above second embodiment, an inclined surface 204a may be provided in the hole side wall section of the SOG film 204 in the physical guide, as shown in FIG. 17. Forming such a configuration can lead to further improvement in embedment properties of the DSA material into the concave section of the physical guide.

In the above first and second embodiments, the block copolymer (DSA material) has been applied in such amounts that the block copolymer layers 107 and 207 have the same levels of thicknesses as the SOC film 103 and the amorphous carbon film 203, but the amounts of application may be increased or decreased.

Although the block copolymer has been used as the DSA material in the above first and second embodiments, another material may be used which has at least two or more kinds of segments such as a blend polymer that brings about similar phase separation to the block copolymer. Herein, the blend polymer means a polymer with segments not being connected.

Further, although the films 102 and 202 to be processed have been processed using the second polymer sections 108b and 208b as masks after selective removal of the first polymer sections 108a and 208a in the first and second embodiments, the first polymer sections 108a and 208a may not be removed and the films 102 and 202 to be processed may be processed making use of a difference in etching rate between the first polymer sections 108a and 208a and the second polymer sections 108a and 208b.

Further, although the block copolymer layer forms a lamellar-shaped microphase separation pattern in the first and second embodiments, the block copolymer layer may form a cylindrical-shaped microphase separation pattern.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A pattern forming method, comprising;
forming a physical guide, in which at least an upper part of a side wall surface of a concave section is an inclined surface, on a film to be processed;
forming a polymer layer containing at least two kinds of segments inside the concave section of the physical guide;
microphase-separating the polymer layer, to form self-assembled polymer domains including a first polymer section and a second polymer section; and
processing the film to be processed by use of the self-assembled polymer domains.

2. The pattern forming method according to claim 1, comprising:
removing the first polymer section of the self-assembled polymer domains; and
processing the film to be processed, with the second polymer section used as a mask, after removal of the first polymer section.

3. The pattern forming method according to claim 1, further comprising:
forming a first film on the film to be processed;
forming a second film on the first film;
forming a hole pattern with a hole side wall section being an inclined surface in the second film; and
after forming the hole pattern, processing the first film by use of the second film as a mask to form the physical guide.

4. The pattern forming method according to claim 3, wherein the first film is an SOC film, and the second film is an SOG film.

5. The pattern forming method according to claim 3, wherein the second film has higher water repellency than the first film.

6. The pattern forming method according to claim 5, wherein the first film is an amorphous carbon film, and the second film is an SOG film.

7. The pattern forming method according to claim 1, wherein
the physical guide has three or more laminated layers, and
a portion corresponding to a film of top layer out of the side wall surface is an inclined surface.

8. The pattern forming method according to claim 7, wherein a film of the top layer has the highest water repellency out of the films constituting the physical guide.

9. The pattern forming method according to claim 1, wherein
the physical guide has a single-layer structure, and
the whole of the side wall surface is an inclined surface.

10. The pattern forming method according to claim 1, wherein an angle formed between the inclined surface and the film to be processed is about 70°.

11. A pattern forming method, comprising;
forming a physical guide, with its upper part having higher water repellency than its lower part, on a film to be processed;
forming a polymer layer containing at least two kinds of segments inside the physical guide;
microphase-separating the polymer layer, to form self-assembled polymer domains including a first polymer section and a second polymer section; and
processing the film to be processed by use of the self-assembled polymer domains.

12. The pattern forming method according to claim 11, comprising:
removing the first polymer section of the self-assembled polymer domains; and
processing the film to be processed, with the second polymer section used as a mask, after removal of the first polymer section.

13. The pattern forming method according to claim 11, further comprising:
forming a first film on the film to be processed;
forming a second film having higher water repellency than the first film on the first film; and
forming a hole pattern, in the second film and the first film, to form the physical guide.

14. The pattern forming method according to claim 13, wherein the first film is an amorphous carbon film, and the second film is an SOG film.

15. The pattern forming method according to claim 13, wherein an inclined surface is formed on a hole side wall section of the first film at the time of forming the hole pattern.

16. The pattern forming method according to claim 15, wherein an angle formed between the inclined surface and the film to be processed is about 70°.

17. The pattern forming method according to claim 11, wherein
the physical guide has three or more laminated films, and
a film of the top layer has the highest water repellency out of the films constituting the physical guide.
